(19) United States
(12) Patent Application Publication
(10) Pub. No.: US 2013/0341762 A1
(43) Pub. Date: Dec. 26, 2013

(54) SEMICONDUCTOR HOLE STRUCTURE

(71) Applicant: YUAN-CHIEH CHIU, Zhubei (TW)

(72) Inventor: YUAN-CHIEH CHIU, Zhubei (TW)

(73) Assignee: MACRONIX INTERNATIONAL CO., LTD., Hsinchu (TW)

(21) Appl. No.: 13/527,931

(22) Filed: Jun. 20, 2012

(51) Int. Cl. H01L 23/48; H01L 21/302

(52) U.S. Cl. 257/618; 438/701; 257/E21.214; 257/E23.011

(57) ABSTRACT

A semiconductor device has a first layer formed on a substrate. A mask layer is formed and patterned above the first layer. The first layer is etched partially through. A second layer is formed over the first layer. The first and second layers are etched by a non-lithography process.

### BACKGROUND

The present application relates generally to semiconductor devices and includes methods and structures for improving hole structures.

An important capability for manufacturing reliable integrated circuits is to precisely shape the individual structures that form the integrated circuits. One such structure is a contact hole. Conducting material may be deposited into a formed contact hole to provide a vertical electrical pathway between horizontal layers within an integrated circuit. Integrated circuits may comprise multiple layers, and contact holes and vias are implemented between each layer to allow electrical communication between neighboring layers. Conventional integrated circuits may require millions of contact holes with a precise uniform width or critical dimension (CD).

Reduction in the dimension of integrated circuits leads to a reduction in the allowable critical dimension of the hole structure. Constructing hole structures therefore becomes difficult within a decreasing allowable process window for layer to layer alignment. Further, high aspect ratio hole structures (small holes with sidewalls having a steep slope or bowing profile) are difficult to fill in with conducting material and achieve a uniform deposition of the conducting material on/in the structure.

Thus, it is desirable to find new approaches for improving hole/via structures, and methods of making the same, for smaller CD holes/vias.

### SUMMARY

According to an aspect, a first layer is formed on a substrate. A mask layer is formed and patterned above the first layer. The first layer is etched partially through. A second layer is formed over the first layer. The first and second layers are etched by a non-lithography process.

According to another aspect, a semiconductor device includes a substrate, a first layer and a second layer. The first layer is formed on the substrate and has a hole extending partially through the first layer. The second layer is formed on the first substrate and sidewalls of the hole of the first layer. The second layer has a thickness less than half of a dimension of the hole.

According to another aspect, a semiconductor device includes a substrate, a first layer and a second layer. The first layer is formed on the substrate and has a hole extending through the first layer. The hole has a first portion distal to the substrate and extending partially through the first layer having a first width. The hole has a second portion extending from the first portion towards the substrate and through the first layer having a second width at a location near the substrate. The second width is smaller than the first width.

### BRIEF DESCRIPTION OF THE DRAWINGS

FIG. 1 are a cross-sectional view of a semiconductor device.

FIG. 2 are a cross-sectional view of forming a hole in a semiconductor device.

FIG. 3 are a cross-sectional view of a semiconductor device.

FIG. 4 are a cross-sectional view of trench isolation, similar trench structures and other trench structure applications.

### DETAILED DESCRIPTION

As semiconductor devices move towards a 60 nm-node (and smaller) technology, hole structures such as contacts and vias require much smaller critical dimensions (CDs) for an allowable process window of overlay. The CD of a hole structure, for example of a contact, is required to be tightly controlled to gain layer-to-layer alignment. In some cases, the CD is smaller than a minimum resolution of the photolithography process.

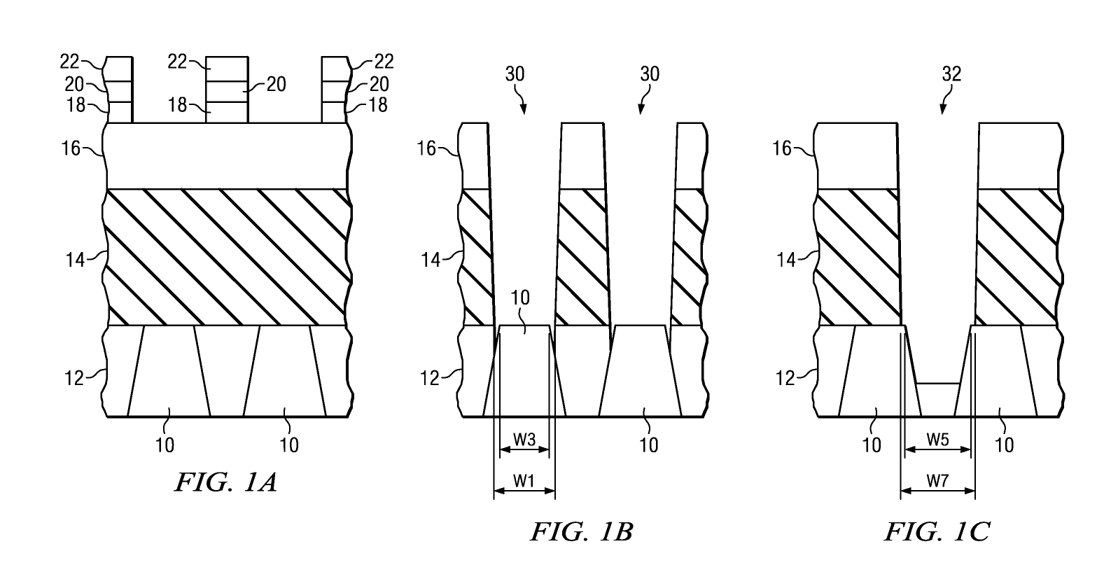

FIG. 1 are a cross-sectional view of a semiconductor device. The underlayer structures 10 are formed in the base layer 12. An interlayer dielectric layer 14 is formed over the underlayer structures 10 and the base layer 12. The interlayer dielectric layer 14 may be an oxide, SiN, SiON, Poly, some combination thereof, or another suitable material. An advanced patterning film 16 is formed over the interlayer dielectric layer 14. The advanced patterning film 16 may be SiN, SiON, oxide, TiN, amorphous carbon (APF), an Si-rich bottom antireflective coating (SHB), an organic under-layer resist (ODL, some combination thereof, or another suitable material. The interlayer dielectric layer 14 and the advanced patterning film 16 are generally different materials from each other to provide better definition of the pattern and to prevent damage to the interlayer dielectric layer 14 from etch chemistry that may be used to remove the advanced patterning film 16.

Referring to FIG. 1A, a dielectric antireflective coating 18, a bottom antireflective coating 20, and a photoresist 22 are formed and patterned over the advanced patterning film 16. The photoresist 22 may be any kind of feasible 193 nm photoresist or another suitable photoresist.

Referring to FIG. 1B, holes 30 are formed by an etch, such as a dry etch, and removal of the dielectric antireflective coating 18, the bottom antireflective coating 20, and the photoresist 22.

Etching a structure such as that shown in FIG. 1A through the interlayer dielectric layer 14 can result in the undesirable condition that a width W1 of the hole 30 at an intersection with the underlayer structure 10 is greater than a width of a top surface W3 of the underlayer structure 10.

Referring to FIG. 1C, a hole 32 is etched using a photoresist pattern similar to that shown in FIG. 1A but patterned to correspond with a hole between the underlayer structures. Such an etching results in the undesirable condition that a width W7 of the hole 32 where the hole 32 reaches the underlayer structures 10 is wider than a width W5 between the underlayer structures 10.

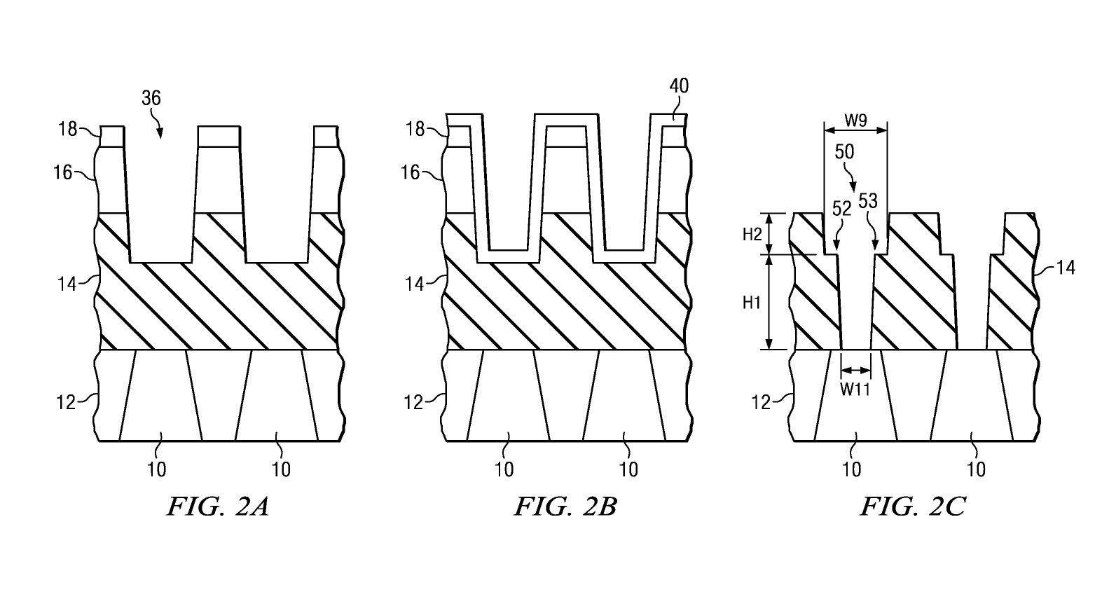

FIG. 2 are a cross-sectional view of forming a hole in a semiconductor device. The semiconductor device is first prepared as shown in FIG. 1A. Then, as shown in FIG. 2A, an O₂ plasma etch is performed to etch through the advanced patterning film 16. The antireflective coating 20 and the photoresist 22 are also removed at the same time. The chemistry of the performed etch may offer good etch selectivity towards the dielectric antireflective coating 18 to limit loss of the dielectric antireflective coating 18. Another in-situ dry etch is used for partially removing material through the interlayer dielectric layer 14 and form a hole 36. The etch depth of the interlayer dielectric layer 14 is controlled by the duration the etching process is carried out.

Referring to FIG. 2B, a film 40, which may be an oxide material, is deposited in the presence of the advanced patterning film 16 at a relatively low temperature, for example less than 150° C. The deposition at a low temperature prevents or reduces damage or removal of the advanced patterning film 16 and associated structures defined by the advanced patterning film 16. The film 40 is a different material from the advanced patterning film 16, which functions as a hard mask. The use of a different material for the film 40 than that of the advanced patterning film 16 allows for better step coverage deposition behavior particularly in a high aspect ration hole structure. The film 40 may have a thickness less than one half of a width of a bottom dimension of a formed hole. In some embodiments, the film 40 may be less than 20 nm.

Referring to FIG. 2C, an anisotropic etch is performed and the film 40 and the advanced patterning film 16 are removed to form the hole 50. The advanced patterning film 16 may be an ashable material. Thus, the removal of the advanced patterning film 16 may also remove the dielectric antireflective coating 18, the bottom antireflective coating 20 and the photo resist 22, if present at the time the advanced patterning film 16 is removed.

The hole 50 has a width W9 near an upper portion of the hole 50 that is greater than a width W11 where the hole 50 intersects with the underlying structure 10. In some embodiments, the top of the underlayer structure 10 may have a top dimension of less than 80 nm (or in some embodiments less than 60 nm) and the width W11 is less than the top dimension of the underlayer structure.

The hole 50 has a stair like shape including protrusions 52 and 53 inwards towards a center line of the hole 50. The slope of the sidewall of the hole 50 may differ above and below the protrusions 52 and 53. The difference between the widths W9 and W11 corresponds to a thickness of the film 40, though it might not be exactly the same. The distance the protrusions 52 and 53 extend towards the center line of the hole 50 also corresponds to the thickness of the film 40, though it might not be exactly the same and it might not be exactly the same as the difference between the widths W9 and W11. Thus, the difference between the widths W9 and W11 and the distance the protrusions 52 and 53 extends towards the center line of the hole 50 can be controlled by the thickness of the film 40. The widths of the protrusion 52 and the protrusion 53 may be equal.

A height H1 from the underlayer structure 10 to the protrusion 52 and a height H2 from the protrusion 52 to a surface of the interlayer dielectric layer 14 may be varied based on the depth of the hole 36 prior to the formation of the film 40. This allows for the control of the aspect ratio of the narrow lower portion of the hole 50 allowing for a more uniform deposition of a fill in material deposited in the hole 50.

Forming the hole 36 with the use of a spacer like the film 40 allows the use of a non-lithography process for etching instead of a damascene process. Thus, the formed hole 36 may be perpendicular symmetric.

Using the above-described process, it becomes possible to create a contact hole have a CD that is smaller than a limit of the photolithography process. For example, a 193 nm photo resist previously thought to be limited to define structures greater than 80 nm can be used with the above-described process to achieve smaller dimension features such as 60 nm or less. Exemplary applications for the above-described small CD hole include floating gate memory, charge trapping memory, non-volatile memory and embedded memory, though it will be appreciated that there are many more applications.

One exemplary advantage is the formation of a small CD hole near a contact for an underlayer structure that slopes (and in some cases includes two different slopes) towards the contact. Thus, conducting material deposited in the hole flows more easily to the contact as compared to a high aspect ratio hole providing better material fill-in performance.

Another exemplary advantage is that the layer (e.g., layer 40) applied after the mask layer can fill in holes, seams or cracks that are present in the mask layer due to an error in the formation of the mask layer. Thus, piping issues, for example seams or cracks formed in an oxide layer, can be reduced by being filled in by the layer.

Another exemplary advantage is the reduction or elimination of piping issues that prevent the interconnection of hole structures through spaces, such as seams or cracks, in a layer (e.g., interlayer dielectric layer 14) and the prevention of contact/via shorts.

It will be appreciated that the layer (e.g., layer 40) can be deposited on a number of other layers including a photoresist, a photoresist like layer, a carbon layer or pattern films to improve a variety of hole structures found in semiconductor devices. Also, it will be appreciated that the process can be applied at various structure layers in a semiconductor device such as periphery contact holes, vias and trench.

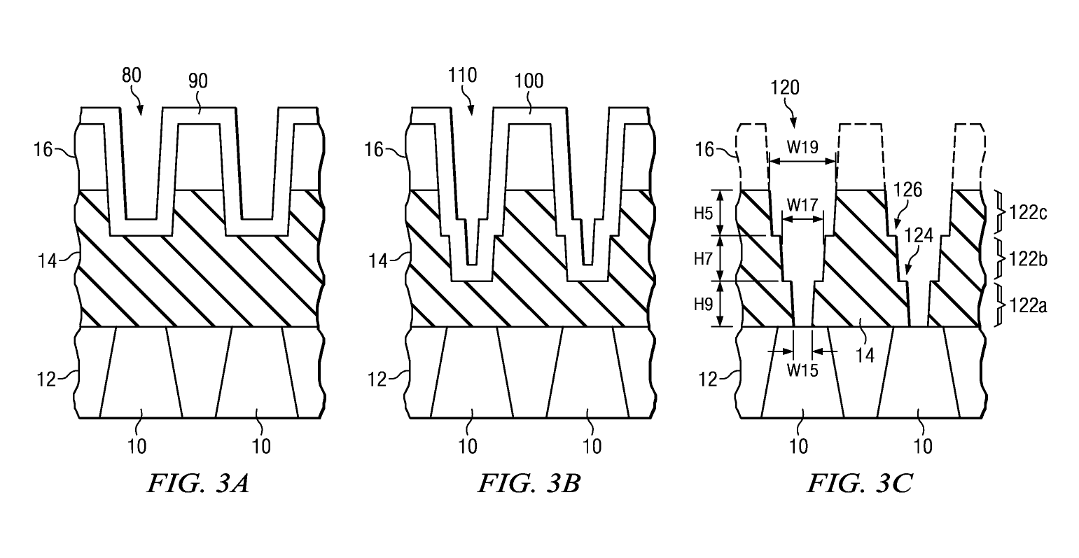

The above-described process may be repeated several times as shown by FIG. 3.

Referring to FIG. 3A, underlayer structures 10 are formed in the base layer 12. The interlayer dielectric layer 14 is formed over the underlayer structures 10 and the base layer 12. The advanced patterning film 16 is formed over the interlayer dielectric layer 14. A hole 80 has been formed through the advanced patterning film 16 and partially through the interlayer dielectric layer 14. After etching the hole 80, the film 90, which may be an oxide film, is formed. The film 90 may be deposited in the presence of the advanced patterning film 16 at a relatively low temperature, for example less than 150° C.

Referring to FIG. 3B, an anisotropic etch is performed on the structure of FIG. 3A and, subsequently, a film 100, which may be an oxide film, is formed. The anisotropic etch is performed long enough that the hole 110 now extends further towards the underlayer structure 10, but not through the interlayer dielectric layer 14. The film 100 may be deposited in the presence of the advanced patterning film 16 at a relatively low temperature, for example less than 150° C.

Referring to FIG. 3C, a second anisotropic etch is performed on the structure of FIG. 3B. The second anisotropic etch is performed long enough to extend the hole through the interlayer dielectric layer 14 to the underlayer structure 10. The advanced patterning film 16 may then be removed.

The hole 120 includes three portions. A first portion 122a near the substrate 10 has a smallest width W15. A second portion 122b in the intermediate region has a width W17 larger than the width W15. A third portion 122c near the surface of the interlayer dielectric layer 14 has a width W19 larger than the width W17. The hole 120 includes an inward protrusion 124 between the portions 122a and 122b and an inward protrusion 126 between the portions 122b and 122c extending towards a centerline of the hole 120.

The width W19 may be controlled by a size of a mask applied in the patterning associated with the hole 80. The width W19 may be slightly larger than a width associated with the mask corresponding with the hole 80 due to loss of material in the etching processes.

The difference between the widths W17 and W19 may be controlled by the thickness of the film 90. The difference between the widths W15 and W17 may be controlled by the thickness of the film 100.

The height H5 of the third portion 122c may be controlled by a duration of an etching process in the formation of the hole 80. The height H7 of the second portion 122b may be controlled by a duration of the first anisotropic etch. The height H9 of the first portion 122a may be controlled by adjusting the heights H5 and H7 in consideration of a thickness of the interlayer dielectric layer 14.

Thus, it will be appreciated that a wide variety of hole profiles can be obtained.

The invention is not limited to contact holes and also applies, for example, to structures for trench isolation, similar trench structures and other trench structure applications.

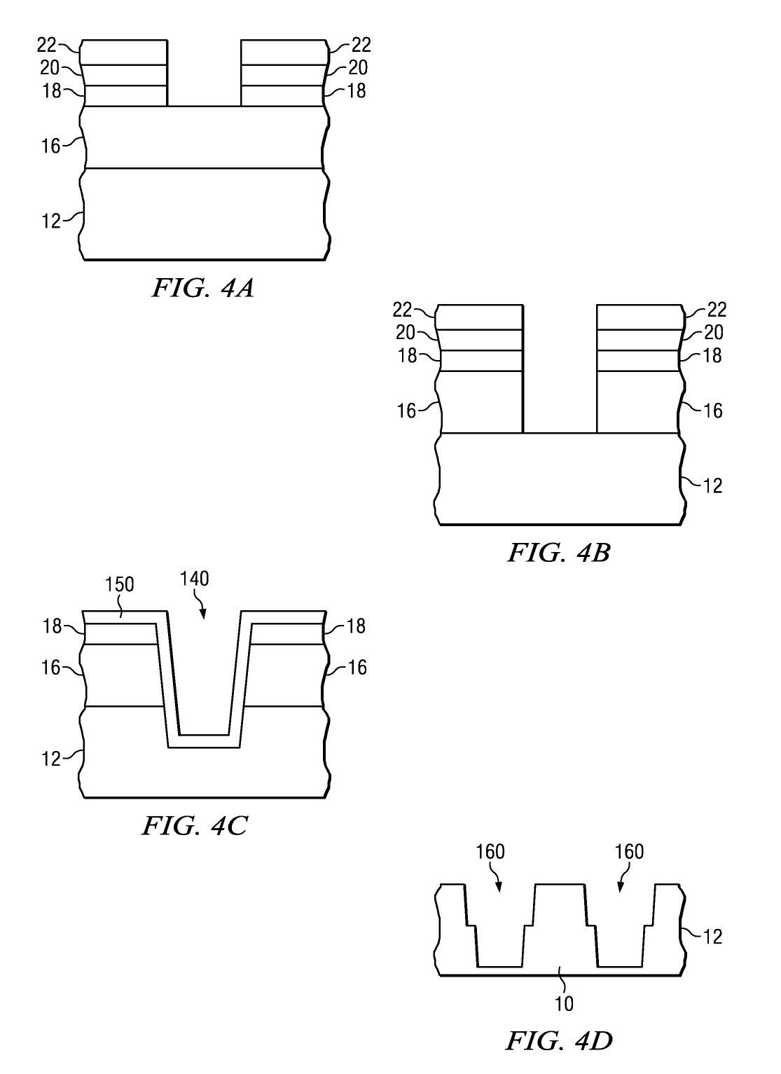

Referring to FIG. 4A, the advanced patterning film 16 is formed over the base layer 12. The dielectric antireflective coating 18 is formed over the advanced patterning film 16. The bottom antireflective coating 20 is formed over the dielectric antireflective coating 18. The photo resist 22 is formed over the bottom antireflective coating 20. The dielectric antireflective coating 18, the bottom antireflective coating 20 and the photo resist 22 are shown after being patterned.

Referring to FIG. 4B, an etch is performed through the advanced patterning film 16 exposing the base layer 12. Referring to FIG. 4C, the etch continues partially through the base layer 12 to form a trench 140. After etching the trench 140, the bottom antireflective coating 20 and the photo resist 22 may be removed and the film 150, which may be an oxide film is formed. The film 150 may be deposited in the presence of the advanced patterning film 16 at a relatively low temperature, for example less than 150° C.

Referring to FIG. 4D, an anisotropic etch is performed on a structure such as that of FIG. 4C. The anisotropic etch is performed long enough that the trenches 160 now extend through the base layer 12 to isolate the underlayer structure 10. The trenches 160 may be filled with a dielectric material such as SiO2.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A method of forming a semiconductor structure, comprising:
forming a first layer on a substrate;
forming and patterning a mask layer above the first layer;
etching partially through the first layer;
forming a second layer over the first layer; and
etching through the first and second layers by a non-lithography process.

2. The method of claim 1, further comprising:
etching, with an anisotropic etch after the forming the second layer, partially through the first layer; and
forming, before the etching through the first layer, a fourth layer over the first layer.

3. The method of claim 1, wherein
the etching forms a hole in the first layer, and
a width of the hole at a portion distal to the substrate is greater than a width of the hole at a portion near the substrate.

4. The method of claim 1, wherein
a sidewall of the hole includes an inward protrusion towards a centerline of the hole,
a second sidewall of the hole includes a second inward protrusion towards the centerline of the hole, and
a width of the inward protrusion and a width of the second inward protrusion are substantially the same.

5. The method of claim 3, wherein the width of the hole at the portion near the substrate is 60 nm or less.

6. The method of claim 3, wherein the hole is perpendicular symmetric.

7. A semiconductor device, comprising:
a substrate;
a first layer formed on the substrate, the first layer having a hole extending partially through the first layer; and
a second layer formed on the first substrate and sidewalls of the hole of the first layer, the second layer having a thickness less than half of a width of the hole.

8. The semiconductor device of claim 7, further comprising:
a third layer formed over the first layer, wherein
the third layer is formed of a material different than a material of the first layer,
the hole extends through the third layer, and
the second layer is formed on the sidewalls of the third layer.

9. A semiconductor device, comprising:
a substrate; and
a first layer formed on the substrate, the first layer having a hole extending through the first layer, wherein
the hole has a first portion distal to the substrate and extending partially through the first layer having a first width,
the hole has a second portion extending from the first portion towards the substrate and through the first layer having a second width at a location near the substrate, and
the second width is smaller than the first width.

10. The semiconductor device of claim 9, wherein a sidewall of the hole includes an inward protrusion towards a centerline of the hole.

11. The semiconductor device of claim 9, wherein the protrusion is located between the first and second portions of the hole.

12. The semiconductor device of claim 9, wherein the protrusion includes a surface substantially parallel to at least one of the substrate and a surface of the first layer.

13. The semiconductor device of claim 9, wherein the width of the hole at the portion near the substrate is 60 nm or less.

14. The semiconductor device of claim 9, wherein
the substrate includes an underlayer structure, and
the width of the hole at the portion near the substrate is smaller than a width of the portion of the underlayer structure adjacent to the first layer.

15. The semiconductor device of claim 9, wherein
the substrate includes at least two underlayer structures, and
the second portion of the hole extends through the first layer and into the substrate between the underlayer structures.

16. The semiconductor device of claim 15, wherein a width of a bottom of the hole in the substrate is smaller than a distance separating the underlayer structures.

17. The semiconductor device of claim 9, wherein the hole is perpendicular symmetric.

18. A semiconductor device, comprising:
an underlayer structure having a top surface with a top dimension; and
a hole structure having a stair like shape with a bottom dimension, wherein
the bottom dimension of the hole is less than the top dimension of the underlayer structure.

19. The semiconductor device of claim 18, wherein the top dimension is less than 80 nm.

20. The semiconductor device of claim 18, wherein the hole structure is perpendicular symmetric.
